(19) United States
(12) Patent Application Publication
(10) Pub. No.: US 2023/0386980 A1
(43) Pub. Date: Nov. 30, 2023

(54) METHOD OF MANUFACTURING SEMICONDUCTOR DEVICES AND CORRESPONDING SEMICONDUCTOR DEVICE

(71) Applicant: STMICROELECTRONICS S.r.l., Agrate Brianza (IT)

(72) Inventors: Michele DERAI, Milano (IT); Guendalina CATALANO, Milano (IT)

(73) Assignee: STMICROELECTRONICS S.r.l., Agrate Brianza (IT)

(21) Appl. No.: 18/324,897

(22) Filed: May 26, 2023

(30) Foreign Application Priority Data
May 31, 2022 (IT) 102022000011561

(51) Int. Cl. H01L 23/495; H01L 23/29; H01L 21/56; H01L 23/00; H01L 23/498

(52) U.S. Cl. CPC H01L 23/49513; H01L 23/29; H01L 21/563; H01L 24/03; H01L 24/05; H01L 23/49827; H01L 2224/05009; H01L 2224/05155; H01L 2224/05164; H01L 2224/05124; H01L 2224/05147

(57) ABSTRACT

A semiconductor die is attached on a die-attachment portion of a substrate such as a leadframe. The semiconductor die has a front surface opposite the substrate and one or more contact pads at the front surface having an outer surface finishing of a first electrically conductive material such as NiPd or Al. An encapsulation of laser direct structuring, LDS material is molded onto the semiconductor die attached on the substrate. Laser beam energy is applied to selected locations of the front surface of the encapsulation of LDS material to activate the LDS material at the selected locations and structure therein electrically conductive formations comprising one or more vias towards the contact pad. The vias comprise a second electrically conductive material that is different from the first electrically conductive material of the outer surface finishing of the contact pad. Prior to growing the second electrically conductive material a nickel layer is formed over the outer surface finishing of the contact pad, wherein the nickel layer promotes adhesion between the second electrically conductive material and the first electrically conductive material.

### BACKGROUND

### Technical Field

The present disclosure relates to manufacturing semiconductor devices including bonding pad finishing in direct copper interconnect (DCI)/laser direct structuring (LDS) processes.

### Description of the Related Art

DCI/LDS processes are expected to play an ever-increasing role in manufacturing semiconductor devices.

Increased use of these technologies involves dealing with various constraints related, e.g., to bonding pad finishing and to electrical wafer sorting (EWS—the operation of electrically testing dice on a semiconductor wafer).

For instance, a possible constraint related to semiconductor (e.g., silicon) pad finishing lies in that via/pad adhesion reasons cause plating on Cu (copper) being almost invariably limited to Cu. Solutions also exist involving front-end (FE) process steps such as sputtering to deposit a seed layer to facilitate adhesion between Cu vias and an underlying pad: however, such an approach is complex and expensive.

### BRIEF SUMMARY

The present disclosure is directed to at least addressing the issues discussed above and herein.

One or more embodiments of the present disclosure also relate to a corresponding semiconductor device.

The present disclosure and the embodiments of the present disclosure presented herein can be used as plug & play feature added to conventional technologies using copper Damascene backend.

The present disclosure provides herein a DCI/LDS integration scheme with an additional nickel electroless step before copper electroless plating. Nickel was found to provide good growth/adhesion to nickel-palladium (NiPd) or aluminum capping (AluCap or AlCap) finishing.

The present disclosure and the embodiments of the present disclosure are thus compatible, e.g., with different types of copper pad finishing (NiPd or Al, for instance), with no additional machining required or changes in the far back end of line (FarBEOL) process, that is in that portion of the processing line intended to form a metal layer (e.g., a redistribution layer) and corresponding on-chip and off-chip interconnect structures.

The present disclosure and the embodiments of the present disclosure provided herein thus have a (very) low impact on unit cost in comparison with conventional solutions.

The present disclosure and at least one embodiment of the present disclosure presented herein includes an LDS process with a double electroless deposition process (nickel and then copper), LDS processing to provide through mold vias (TMVs) landing on die bonding pads with Al or NiPd finishing. A corresponding semiconductor device will thus exhibit LDS/DCI vias landing on, e.g., Al or NiPd finished die bonding pads, with, e.g., a twin nickel-plus-copper seed layer detectable in the through mold vias.

The present disclosure and the embodiments of the present disclosure herein facilitate achieving one or more of the following goals:
removing wires from Quad-Flat No-leads (QFN) packages, thus achieving improved flexibility in current distribution and facilitating integration of passive components in a device package;
leaving metal pads exposed as in current QFN design for thermal dissipation (e.g., via soldering on a printed circuit board, PCB); and
enlarging the device plateau for LDS/CDI packs (different metal finishing can be used).

### BRIEF DESCRIPTION OF THE SEVERAL VIEWS OF THE DRAWINGS

One or more embodiments will now be described, by way of example only, with reference to the annexed figures, wherein:

FIG. 1 is a cross-sectional view of a semiconductor device to which embodiments of the present description can apply,

FIG. 2 is a view of the portion of FIG. 1 indicated by arrow II, reproduced on an enlarged scale, showing a possible application of embodiments of the present description in a device as illustrated in FIG. 1,

FIGS. 3A to 3I are exemplary of possible sequence of steps in implementing embodiments of the present description,

FIGS. 4, 5 and 6 are plan views of a semiconductor device structure exemplary of the results of various steps in the sequence of FIGS. 3A to 3I, and

FIG. 7 is a more detailed view of the portion of FIG. 1 indicated by arrow II, reproduced on the enlarged scale, showing a possible application of embodiment of the present disclosure in a device as illustrated in FIG. 1.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

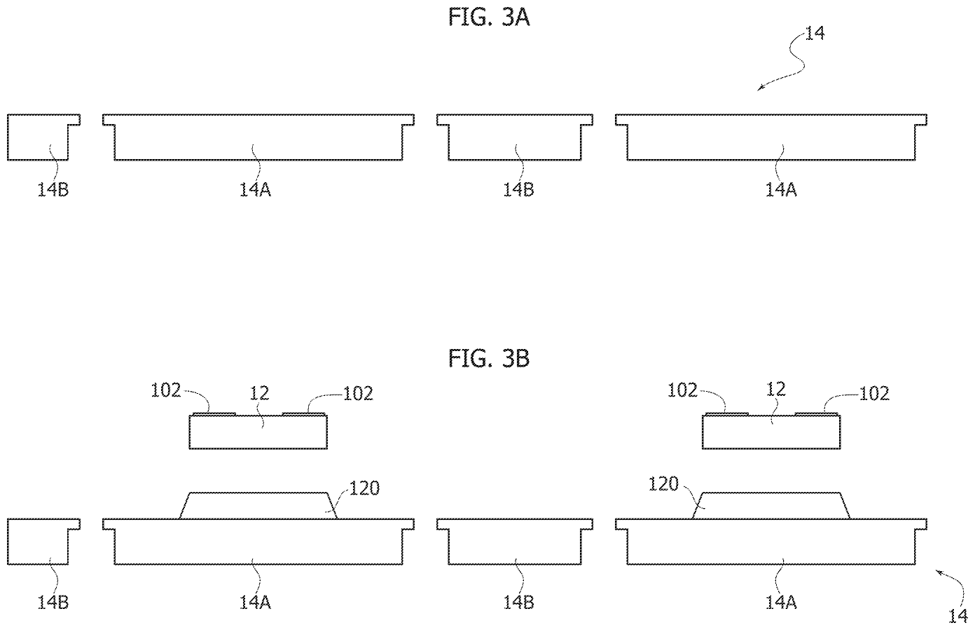

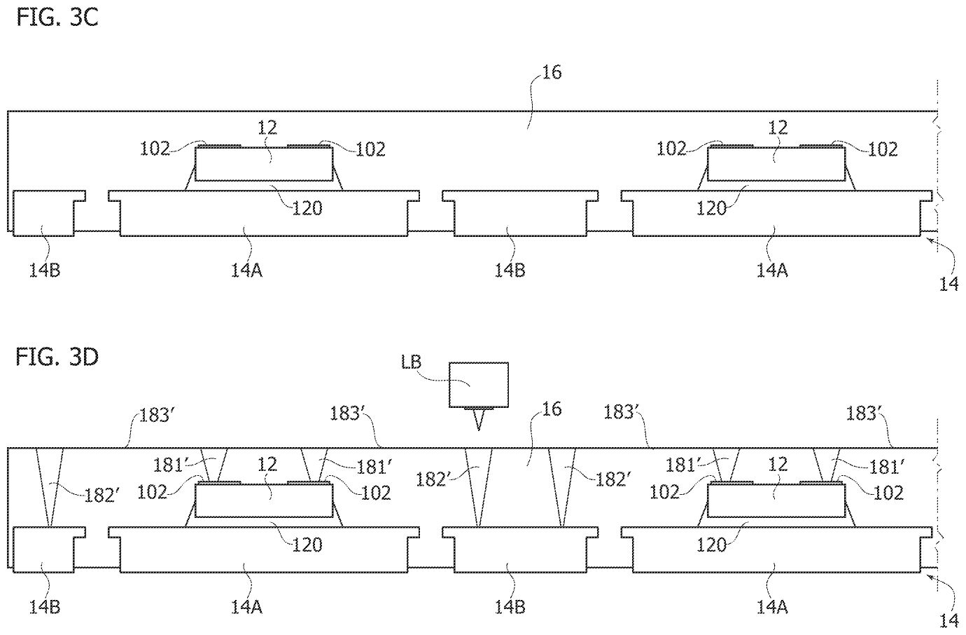

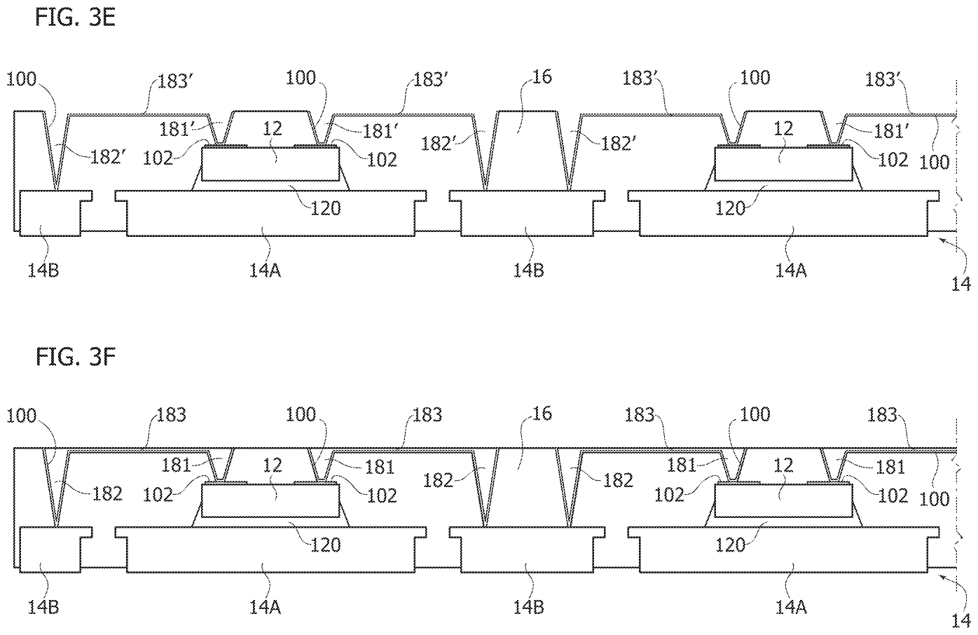

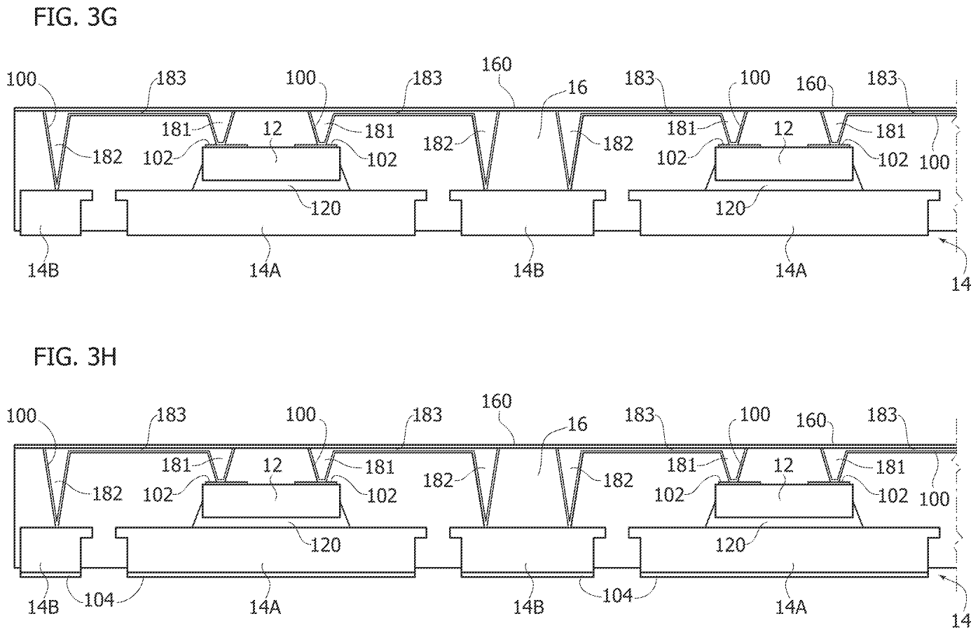

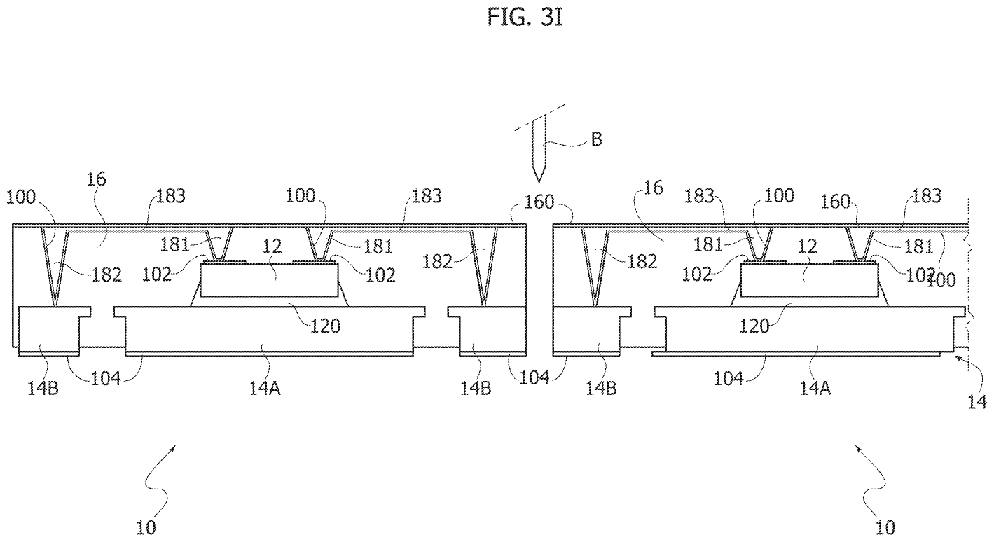

For simplicity and ease of explanation, throughout this description:
like parts or elements are indicated in the various figures with like reference signs, and a corresponding description will not be repeated for each and every figure, and
manufacturing a single device will be primarily described, being otherwise understood that in current manufacturing processes plural semiconductor devices are manufacturing concurrently, with these devices finally separated into individual devices in a singulation step (see FIG. 3I).

Various definitions that are well known to those of skill in the art are recalled here in order to facilitate reading the present detailed description.

QFN Package: Quad Flat No-Leads, a package that has leads incorporated in the bottom side of the package encapsulation (molding compound), that is, no leads protruding or projecting radially of the package.

RDL (ReDistribution Layer): an extra metal layer on a chip that provides input/output (I/O) pads of an integrated circuit available in other locations.

LDS: Laser direct structuring, LDS is a laser-based machining technique now widely used in various sectors of the industrial and consumer electronics markets, for instance for high-performance antenna integration, where an antenna design can be directly formed onto a molded plastic part. In an exemplary process, the molded parts can be produced with commercially available insulating resins that include additives suitable for the LDS process; a broad range of resins such as polymer resins like PC, PC/ABS, ABS, LCP are currently available for that purpose. A laser beam can be used to transfer (“structure”) a desired electrically conductive pattern onto a plastic molding that may then be subjected to metallization to finalize a desired conductive pattern. Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

LDS is oftentimes referred to also as direct copper interconnection, DCI. This is primarily with reference to a package family wherein conventional wire bonding is replaced with copper plated vias and lines (traces). Laser Induced Strip Interconnection, LISI is another designation used for DCI packages where LDS technology is used for creating vias and traces in a resin.

As discussed, a possible constraint related to semiconductor (silicon) pad finishing in these processes lies in that achieving adequate via/pad adhesion causes Cu to be an almost exclusive candidate for plating on Cu (that is a same material used for pad finishing and plating thereon). Other solutions implement front-end (FE) process steps such as sputtering to deposit a seed layer to facilitate adhesion between Cu vias and an underlying pad: however, such an approach is complicated and expensive.

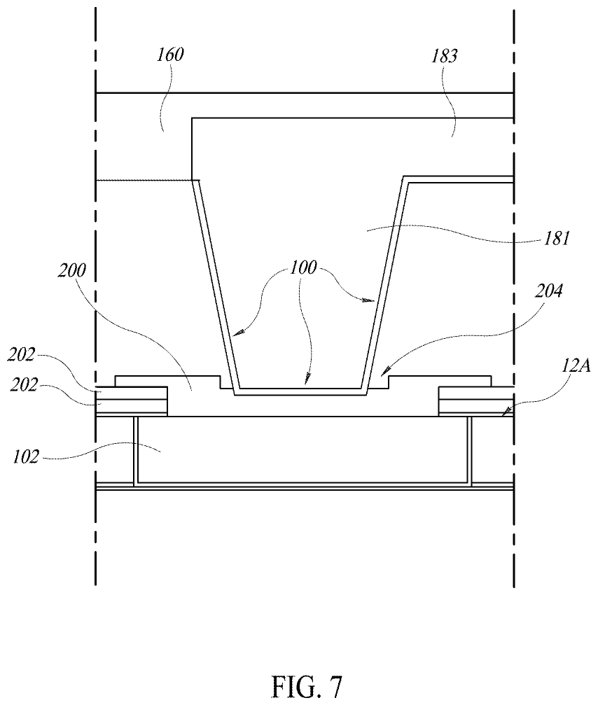

In embodiments as described herein, a nickel electroless layer is provided in order to enhance (e.g., Cu) vias adhesion on different metal pad finishing (e.g., NiPd and Al). See, for example, FIG. 7 of the present disclosure.

To that effect a nickel electroless plating step is added before Cu plating (electroless plus electrolytic growth) in order to create a junction layer between a Cu via and the underlying metal pad.

A zincate plating process can be advantageously added in order to improve adhesion of the electroless nickel layer.

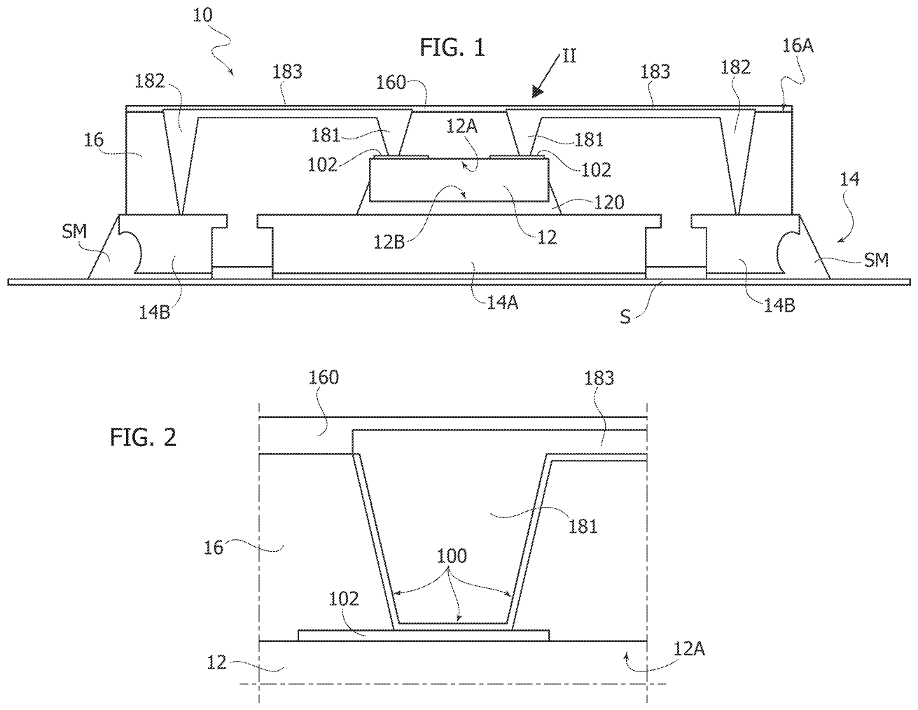

FIG. 1 is a cross-sectional view of a semiconductor device 10 (e.g., a device in a QFN package) showing possible parts/elements therein.

In the example presented in FIG. 1, a semiconductor device 10 comprises a semiconductor die or chip 12 arranged (e.g., via die-attach material 120) on a substrate such as a leadframe 14. As illustrated, the leadframe 14 comprises a die pad 14A surrounded by an array of electrically conductive leads 14B to provide electrically conductive paths to and from the semiconductor die or chip 12.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically conductive formations (or leads, e.g., 14B) that from an outline location extend inwardly in the direction of a semiconductor chip or die (e.g., 12) thus forming an array of electrically conductive formations from a die pad (e.g., 14A) configured to have at least one semiconductor chip or die attached thereon. This may be accomplished via a die attach adhesive 120 (a die attach film or DAF, for instance).

The semiconductor chip or die 12 includes one or more electrical components, such as integrated circuits.

An insulating encapsulation 16 is molded onto the chip(s) 12. The insulating encapsulation 16 molded onto the chip(s) 12 includes an additive material that is activated when exposed to a laser. The additive material becomes electrically conductive when exposed to the laser.

In arrangements as exemplified in FIG. 1, the semiconductor die or chip 12 may be regarded as having a first (“top” or “front”) surface 12A, and a second (“bottom” or “back”) surface 12B towards the leadframe 14, which may act as a supporting substrate for the semiconductor die or chip 12. The first surface 12A of the chip 12 is opposite to the second surface 12B of the chip.

As noted, throughout the figures, parts or elements like parts or elements introduced in connection with FIG. 1 will be indicated with like references, and a corresponding description will not be repeated for the sake of brevity and simplicity of the present disclosure. Also, in order to avoid making the graphical representation unnecessarily complicated, certain parts or elements visible/referenced in one figure may not be visible/referenced in other figures.

As well known to those of skill in the art, a semiconductor device such as the device 10 illustrated in FIG. 1 may comprise fewer or more parts/elements than those exemplified in FIG. 1 and one or more of the parts exemplified in FIG. 1 can be replaced by other parts/elements. Also, throughout this description, the terms “chip” and “die” will be used as synonyms.

A device 10 as exemplified in FIG. 1 may be referred to as a semiconductor device of the “QFN” package type, QFN being an acronym for Quad Flat No-Leads. It is noted that in a QFN package as exemplified in FIG. 1 (this being, e.g., the case of a so-called flip-chip QFN package) the first (top or front) surface of the die 12A is not directly available for connection to a mounting substrate S (e.g., of the Printed Circuit Board—PCB type), e.g., via solder material SM.

Electrical connection of the first (top or front) surface 12A of the die 12 to the leads 14B in the leadframe 14 may be via a so-called wire bonding layout (e.g., metallic wires) that provide electrical connection between contact pads (see, e.g., the pads 102 in FIGS. 1 and 2) at the top or front surface 12A of the die 12 and corresponding leads 14B in the leadframe 14.

As a possible alternative to such a wire bonding layout, a device 10 as illustrated in FIG. 1 may take advantage of the possibility of using for the encapsulation 16 an LDS material, that is a material comprising a per se insulating matrix (e.g., a resin) that includes additives (e.g., metal oxides) suitable to be “activated” in an LDS process via laser beam energy to transfer (“structure”) therein a desired electrically conductive pattern. The activated/structured pattern can then be subjected to metallization to finalize a desired conductive pattern.

Electrically conductive die-to-lead coupling formations can be provided in the LDS material 16 (once consolidated, e.g., via thermosetting).

As illustrated in FIG. 1 (and in the enlarged view of FIG. 2) such die-to-lead coupling formations comprise:
first through mold vias (TMVs) 181 that extend through the LDS encapsulation 16 between the top (front) surface 16A of the LDS encapsulation 16 and electrically conductive pads 102 at the front or top surface 12A of the chip or die 12,
second through mold vias (TMVs) 182 that extend through the LDS encapsulation 16 between the top (front) surface 16A of the LDS encapsulation 16 and corresponding leads 12B in the leadframe, and
electrically conductive lines or traces 183 that extend at the front or top surface 16A of the LDS encapsulation 16 and electrically couple selected ones of the first vias 181 with selected ones of the second vias 182 to provide a desired die-to-lead electrical connection (routing) pattern between the chip or die 12 and the leads 14B.

This may be in the form of a so-called RDL (ReDistribution Layer). Passive components (e.g., capacitors), not visible for simplicity may be coupled to any of the vias 181, 182 or the electrically conductive lines 183.

The vias 181, 182 can be produced, e.g., by providing (e.g., by laser drilling) holes extending through the packaging material (LDS molding compound) 16, with subsequent processing (e.g., metallization) to facilitate obtaining/increasing electrical conductivity as desired.

In some embodiments, the vias 181, 182 are filled completely with conductive material, while in other embodiments, the vias 181, 182 are lined with conductive material. The passageways lined with conductive material may then be filled with another material. The conductive material in the vias 181, 182 are coupled to the conductive lines 183.

The encapsulation of the device 10 can be provided with a layered structure comprising, e.g., a first layer 16 of LDS material as illustrated in FIGS. 1 and 2 plus a second layer (not visible for simplicity) molded onto the upper surface 16A of the first layer 16 of the encapsulation and the lines 183 formed thereon, so that the first encapsulation layer 16 is sandwiched between the support substrate (leadframe 14) and the second encapsulation layer. The second layer may be a standard (non-LDS) encapsulation material (epoxy resin, for instance), which does not contain the additive material as the first encapsulation material 16.

As noted, the second encapsulation layer is not visible for simplicity. Likewise for simplicity the case is illustrated of a single chip or die 12 mounted on a single die pad 14A, being otherwise understood that various embodiments may include plural chips or dice mounted on a single die pad 14A or on plural die pads 14A. Also, while through mold vias 181, 182 and lines 183 are illustrated providing die-to-lead electrical connections, a similar arrangement can be used to provide die-to-die electrical connection.

Documents such as US 2018/342453 A1, US2019/115287 A1, US 2020/203264 A1, US 2020/321274 A1, US 2021/050226 A1, US 2021/050299 A1, US 2021/183748 A1, or US 2021/305203 A1 (all assigned to the same assignee of the present application) are exemplary of the possibility of applying LDS technology in manufacturing semiconductor devices.

In fact, LDS/DCI technology was found to facilitate replacing wires, clips or ribbons with lines/vias created by laser beam processing of an LDS material followed by metallization (growing metal such as copper via a plating process, for instance).

As repeatedly discussed, a possible constraint in these processes may lie in semiconductor (silicon) pad finishing in these processes, with Cu being an almost exclusive candidate for plating for via/pad adhesion reasons. In embodiments as described herein a nickel electroless layer is provided in order to enhance adhesion of vias (e.g., copper vias such as the vias 181) with pad finishing of a different material like NiPd or Al.

To that effect, a nickel layer 100 (see, e.g., FIG. 2) is added, e.g., via an electroless plating step, before Cu (electroless) growth in order to create a junction layer between a Cu via (see 181 in FIG. 2, for example) and the underlying metal pad 102 that may have a metal pad finishing like NiPd or Al.

FIGS. 3A to 3I are exemplary of a possible sequence of steps in manufacturing a semiconductor device 10 implementing embodiments of the present description.

It will be otherwise appreciated that the sequence of steps of FIGS. 3A to 3I is merely exemplary insofar as:
one or more steps illustrated in FIGS. 3A to 3I can be omitted, performed in a different manner (with other tools, for instance), different order, and/or replaced by other steps;
additional steps may be added;
one or more steps can be carried out in a sequence different from the sequence illustrated.

FIG. 3A is exemplary of providing a substrate 14 such as a (standard) leadframe comprising die pad portions 14A and lead portions 14B.

FIG. 3B is exemplary of chips or dice 12 being attached (e.g., via die attach material 120) onto die pads 14A.

FIG. 3C is exemplary of an encapsulation 16 of LDS material being molded (e.g., via compression molding) onto the leadframe 14 having the chips or dice 12 attached thereon.

FIG. 3D is exemplary of the through-mold vias and the lines therebetween being “structured” or “activated” in the LDS material 16 via laser machining (as symbolized by LB) at corresponding locations of the surface 16A.

These locations for the vias/lines 181, 182 and the lines 183 are indicated by the same reference numbers with an accent “′” in order to highlight the fact that the vias/lines 181, 182 and lines 183 proper will be formed at those locations only after subsequent metal growth as discussed in the following. In other words, the respective laser-beam activated locations 181′, 182′ are openings, recesses, or via openings in which the vias/lines 181, 182 are to be formed, and the respective laser-beam activated locations 183′ are surfaces at which the lines 183 are to be formed. These respective laser-beam activated locations 181′, 182′, 183′ are lined with additive particles that have been activated by the laser beam to form the vias/lines 181, 182 and the lines 183 at these laser-beam activated locations 181′, 182′, 183′.

FIG. 3E is exemplary of nickel plating applied to form a seed layer 100 at the laser-beam activated locations 181′, 182′, 183′ of the LDS material 16.

The LDS material (molding compound) 16 contains additive particles that facilitate growing Ni (e.g., via electroless plating) just like Cu is grown in conventional LDS processing after laser exposure.

That is, the additive particles in the LDS molding compound are “exposed” by laser beam LB and an electroless Ni bath facilitates growing Ni at the locations that were activated (structured) via laser beam exposure.

A Ni layer 100 can thus be grown at those locations where the additives in the LDS compound are exposed.

Nickel plating as considered herein can be electroless nickel plating as known per se to those of skill in the art. Electroless plating, also known as chemical plating, is a class of industrial chemical processes that creates metal coatings on various materials by autocatalytic chemical reduction of metal cations in a liquid bath.

While not visible for scale reasons, a zincate plating process can be advantageously added (prior to the nickel plating step of FIG. 3E) in order to improve adhesion of the electroless nickel layer 100.

FIG. 3F is exemplary of vias/lines 181, 182 and lines 183 being formed by growing Cu on the Ni electroless seed layer 100.

The step represented in FIG. 3F may include distinct plating steps such as electroless Cu plating (onto the Ni see layer 100) followed by galvanic (electrolytic) Cu growth as otherwise conventional in LDS processing; Cu plating/growth thus takes place on the nickel seed layer 100.

It is noted that Cu galvanic growth “on top” of Cu electroless is facilitated thanks to the electrical continuity enabled by the metallic leadframe.

Electrically conductive vias 181, 182 and lines 183 are thus formed the locations 181′, 182′, 183′ that were previously activated via laser beam LB and at which a nickel seed layer 100 has been subsequently formed.

In embodiments as discussed herein, through-mold (e.g., Cu) vias 181, 182 can thus be formed on non-homologous (e.g., non-Cu) metal, such as a pad 102 provided (towards the vias 181, 182, that is at the upper pad surface in the figures) with a non-Cu finishing like NiPd and Al. See FIG. 7 as an example in which an NiPd or Al capping layer is present on a Cu Damascene portion of the die 12.

FIG. 3G is exemplary of a passivation layer 160 formed on the front or top surface of the assembly.

FIG. 3H is exemplary of tin plating of the die pads 14A and the leads 14B in the leadframe 14, as indicated by reference 104 to facilitate mounting/electrical coupling with the support element S (a PCB, for instance).

FIG. 3I is illustrative of a singulation step (e.g., via a blade B) to separate individual devices 10 from the multi-device assembly used in manufacturing (as conventional in the art).

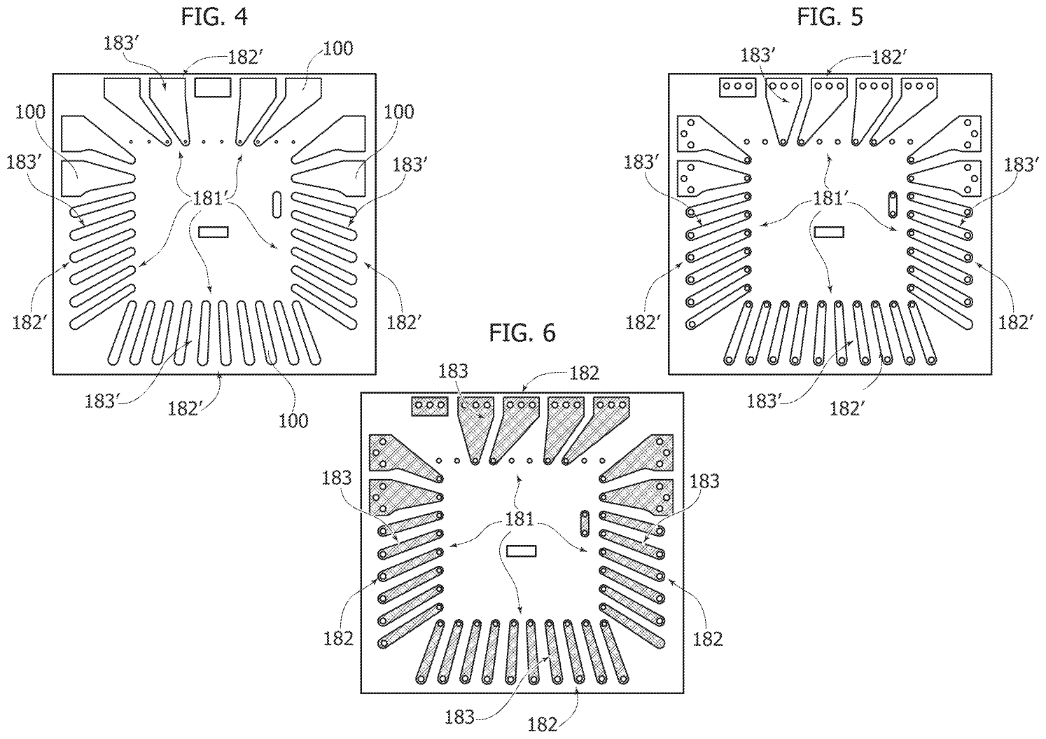

FIG. 4 is a plan view of the structure resulting from the step of FIG. 3E: electroless nickel 100 formed at the laser-activated locations 181′, 182′, 183′.

FIGS. 5 and 6 are plan views of the structure resulting from electroless copper deposition (FIG. 5) and galvanic copper growth (FIG. 6) at the laser-activated (and nickel-plated) locations 181′, 182′, 183′ to provide the vias 181, 182 and the traces 183.

Examples as presented herein thus facilitate creating LDS (CDI/LISI) vias (e.g., Cu vias such as the vias 181) on non-homologous (e.g., non-Cu) metal pad finishing like NiPd and Al. In FIG. 7, a first electrical conductive material (e.g., NiPd, Al, or some other suitable conductive material) 200 is present on the contact 102, which may be made of a copper (Cu) and may be part of a Damascene portion, of the die 12. As shown in FIG. 7, one or more non-conductive layers 202 may be present on the first surface 12A of the die 12. The first electrical conductive material 200 extends onto the one or more non-conductive layers 202. The first electrical conductive material 200 may be referred to as a capping layer.

In examples as presented herein such a result can be achieved via (chemical) deposition of a nickel electroless layer without additional machining or process changes, with no appreciable impact on unit cost in comparison with conventional LDS (CDI or LISI) package processing.

The sequence of FIGS. 3A to 3I thus involves attaching at least one semiconductor die 12 on a die-attachment portion 14A of a substrate 14 such as a leadframe.

The semiconductor die 12 has a first, front surface 12A opposite the substrate 14 and one or more one contact pads 102 at the front surface 12A having an outer surface finishing of the first electrically conductive material 200 such as NiPd or Al.

An encapsulation 16 of laser direct structuring, LDS material is molded onto the semiconductor die or dice 12 attached on the substrate 14.

Laser beam energy LB is applied to selected locations (namely 181′, 182′, 183′) of the front surface 16A of the encapsulation 16 of LDS material to activate the LDS material at the selected locations 181′, 182′, 183′ thus structuring therein electrically conductive formations to the semiconductor die or dice 12. When the laser beam energy LB is applied to the selected locations 181′, the laser beam may form a small indentation, divot, or recess 204 in the first electrical conductive material 200.

The electrically conductive formations 181, 182, 183 comprise one or more vias 181 extending from the front surface 16A of the encapsulation 16 towards the contact pad(s) 102 having the outer surface finishing of the first electrically conductive material 200 such as NiPd or Al.

A second electrically conductive material, which forms the vias/lines 181, 182 and the lines 183, such as Cu is grown at the activated selected locations 181′, 182′, 183′ of the LDS material to provide the electrically conductive formations 181, 182, 183 to the semiconductor die or dice 12.

The second electrically conductive material is, e.g., copper (Cu) and is thus different from the first electrically conductive material (e.g., Ni—Pd or Al) of the outer surface finishing of the contact pad(s) 102.

Prior to growing the second electrically conductive material, a nickel layer 100 is formed over the outer surface finishing (of the first electrically conductive material 200) of the contact pad(s) 102 at the activated selected locations 181′, 182′, 183′ of the LDS material (as depicted in FIG. 3F).

The nickel layer 100 promotes adhesion between the (second) electrically conductive material of the via 181 and the (first) electrically conductive material of the outer surface finishing (of the first electrically conductive material 200) of the contact pad(s) 102.

It will be appreciated that nickel plating 100 as illustrated in FIG. 3E extends, in addition to the distal ends of the vias 181 landing on die pads 102:
to the peripheral (e.g., frusto-conical) side surfaces of the vias 181;
to the vias 182 (distal ends landing on selected ones of the, e.g., copper leads 14B plus the peripheral side surfaces), and
to the surface of the encapsulation 16 lying under the lines 183.

The nickel plating 100 was found to be beneficial in promoting adhesion in a similar manner, for instance, between copper (Cu) as grown at the vias 182 and corresponding copper leads 14B. In other words, an outer finishing of the first electrical conductive material 200 may be present on respective internal surfaces of the leads 14B and the vias 182 may be coupled to the outer surface finishing of the first conductive material 200 at the respective internal surfaces 14B of the leads 14B. In other words, the structure will appear to be the same or similar to the structure as shown in FIG. 7 but is present at the respective internal surfaces of the leads 14B. The internal surfaces of the leads 14B are at least partially covered by the insulating encapsulation 16 as shown in FIG. 1.

Without prejudice to the underlying principles, the details and embodiments may vary, even significantly, with respect to what has been described by way of example only without departing from the extent of protection.

A method, may be summarized as including attaching (120) at least one semiconductor die (12) on a die-attachment portion (14A) of a substrate (14), the at least one semiconductor die (12) having a front surface (12A) opposite the substrate (14) and at least one contact pad (102) at the front surface (12A), the at least one contact pad (102) having an outer surface finishing of a first electrically conductive material, molding onto the at least one semiconductor die (12) attached on the substrate (14) an encapsulation (16) of laser direct structuring, LDS material, the encapsulation of LDS material (16) having a front surface (16A) opposite the substrate (14), applying laser beam energy (LB) to selected locations (181′, 182′, 183′) of the front surface of the encapsulation (16) of LDS material to activate the LDS material at said selected locations (181′, 182′, 183′) and structure therein electrically conductive formations (181, 182, 183) to the at least one semiconductor die (12), the electrically conductive formations (181, 182, 183) including at least one via (181) extending through the encapsulation (16) of LDS material towards said at least one contact pad (102) having said outer surface finishing of the first electrically conductive material, growing a second electrically conductive material at the activated selected locations (181′, 182′, 183′) of the LDS material to form said electrically conductive formations (181, 182, 183) to the at least one semiconductor die (12), wherein the second electrically conductive material is different from the first electrically conductive material of said outer surface finishing, wherein the method includes, prior to growing the second electrically conductive material at the activated selected locations (181′, 182′, 183′) of the LDS material, forming a nickel layer (100) over the outer surface finishing of the first electrically conductive material of the at least one contact pad (102).

The method may include, prior to forming said nickel layer (100), forming a zincate layer over the outer surface finishing of a first electrically conductive material of the at least one contact pad (102), wherein the zincate layer may promote adhesion between the nickel layer (100) and the outer surface finishing of the at least one contact pad (102).

The outer surface finishing of the at least one contact pad (102) may include NiPd or Al finishing.

The method may include growing copper as said second electrically conductive material at the activated selected locations (181′, 182′, 183′) of the LDS material.

Growing said second electrically conductive material at the activated selected locations (181′, 182′, 183′) of the LDS material may include electroless growing a seed layer of said second electrically conductive material.

Growing said second electrically conductive material at the activated selected locations (181′, 182′, 183′) of the LDS material may include electrolytically growing further second electrically conductive material over said electroless grown seed layer.

The method may include electroless plating said nickel layer (100) over the outer surface finishing of the first electrically conductive material of the at least one contact pad (102).

The method may include forming said nickel layer (100) at the activated selected locations (181′, 182′, 183′) of the LDS material.

A device (10), may be summarized as including at least one semiconductor die (12) attached (120) on a die-attachment portion (14A) of a substrate (14), the at least one semiconductor die (12) having a front surface (12A) opposite the substrate (14) and at least one contact pad (102) at the front surface (12A), the at least one contact pad (102) having an outer surface finishing of a first electrically conductive material, an encapsulation (16) of laser direct structuring, LDS material molded onto the at least one semiconductor die (12) attached on the substrate (14), the encapsulation of LDS material (16) having a front surface (16A) opposite the substrate (14), electrically conductive formations (181, 182, 183) to the at least one semiconductor die (12) formed at selected locations (181′, 182′, 183′) of the LDS material, the electrically conductive formations (181, 182, 183) including at least one via (181) extending through the encapsulation (16) of LDS material (16) towards said at least one contact pad (102) having said outer surface finishing of the first electrically conductive material, wherein the at least one via (181) is of a second electrically conductive material, the second electrically conductive material being different from the first electrically conductive material of said outer surface finishing, and a nickel layer (100) over the outer surface finishing of the first electrically conductive material of the at least one contact pad (102).

The device (100) may include a zincate layer between the outer surface finishing of the first electrically conductive material of the at least one contact pad (102) and the nickel layer (100), wherein the zincate layer promotes adhesion between the nickel layer (100) and the outer surface finishing of the at least one contact pad (102).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
attaching at least one semiconductor die on a die-attachment portion of a substrate, the at least one semiconductor die having a front surface opposite the substrate and at least one contact pad at the front surface, the at least one contact pad having an outer surface finishing of a first electrically conductive material,
molding onto the at least one semiconductor die attached on the substrate an encapsulation of laser direct structuring, LDS material, the encapsulation of LDS material having a front surface opposite the substrate,
applying laser beam energy to selected locations of the front surface of the encapsulation of LDS material to activate the LDS material at said selected locations and structure therein electrically conductive formations to the at least one semiconductor die, the electrically conductive formations comprising at least one via extending through the encapsulation of LDS material towards said at least one contact pad having said outer surface finishing of the first electrically conductive material,
growing a second electrically conductive material at the activated selected locations of the LDS material to form said electrically conductive formations to the at least one semiconductor die, wherein the second electrically conductive material is different from the first electrically conductive material of said outer surface finishing,
wherein the method comprises, prior to growing the second electrically conductive material at the activated selected locations of the LDS material, forming a nickel layer over the outer surface finishing of the first electrically conductive material of the at least one contact pad.

2. The method of claim 1, comprising, prior to forming said nickel layer, forming a zincate layer over the outer surface finishing of a first electrically conductive material of the at least one contact pad, wherein the zincate layer promotes adhesion between the nickel layer and the outer surface finishing of the at least one contact pad.

3. The method of claim 1, wherein the outer surface finishing of the at least one contact pad comprises NiPd or Al finishing.

4. The method of claim 1, comprising growing copper as said second electrically conductive material at the activated selected locations of the LDS material.

5. The method of claim 1, wherein growing said second electrically conductive material at the activated selected locations of the LDS material comprises electroless growing a seed layer of said second electrically conductive material.

6. The method of claim 5, wherein growing said second electrically conductive material at the activated selected locations of the LDS material comprises electrolytically growing further second electrically conductive material over said electroless grown seed layer.

7. The method of claim 1, comprising electroless plating said nickel layer over the outer surface finishing of the first electrically conductive material of the at least one contact pad.

8. The method of claim 1, comprising forming said nickel layer at the activated selected locations of the LDS material.

9. A device, comprising:
at least one semiconductor die attached on a die-attachment portion of a substrate, the at least one semiconductor die having a front surface opposite the substrate and at least one contact pad at the front surface, the at least one contact pad having an outer surface finishing of a first electrically conductive material,
an encapsulation of laser direct structuring, LDS material molded onto the at least one semiconductor die attached on the substrate, the encapsulation of LDS material having a front surface opposite the substrate,
electrically conductive formations to the at least one semiconductor die formed at selected locations of the LDS material, the electrically conductive formations comprising at least one via extending through the encapsulation of LDS material towards said at least one contact pad having said outer surface finishing of the first electrically conductive material, wherein the at least one via is of a second electrically conductive material, the second electrically conductive material being different from the first electrically conductive material of said outer surface finishing, and
a nickel layer over the outer surface finishing of the first electrically conductive material of the at least one contact pad.

10. The device of claim 9, comprising a zincate layer between the outer surface finishing of the first electrically conductive material of the at least one contact pad and the nickel layer, wherein the zincate layer promotes adhesion between the nickel layer and the outer surface finishing of the at least one contact pad.

11. A method, comprising:
forming a die attach material on a surface of a die pad of a leadframe;
coupling a die to the die pad by placing the die on the die attach material;
forming an encapsulation material with an additive material on the die, on the die pad of the leadframe, and on a lead of the leadframe;
exposing the encapsulation material with the additive material to a laser including:
forming a first via opening extending into the encapsulation material to a contact pad of the die;
forming a second via opening extending into the encapsulation material to the lead;
activating the additive material of the encapsulation material along a first sidewall surface delimiting the first via opening, along a second sidewall delimiting the second via opening, and a surface of the encapsulation material extending from the first sidewall to the second sidewall;
forming an electrical connection between the lead and the contact pad including:
forming a first conductive material on the contact pad and on the additive material activated on the first sidewall, the second sidewall, and the surface; and
forming a second conductive material different from the first conductive material on the first conductive material.

12. The method of claim 11, wherein forming the first conductive material on the additive material includes plating the first conductive material on the additive material.

13. The method of claim 12, wherein forming the second conductive material on the first conductive material includes plating the second conductive material on the first conductive material.

14. The method of claim 13, further comprising covering the encapsulation material and the electrical connection by forming a passivation layer on the encapsulation material and on the electrical connection.

15. The method of claim 11, wherein forming the first conductive material on the contact pad includes forming the first conductive material on a capping layer of the die on a copper portion of the die.

16. The method of claim 15, wherein the capping layer includes nickel palladium (NiPd).

17. The method of claim 16, wherein the first conductive material includes nickel (Ni) and the second conductive material includes copper (Cu).

18. The method of claim 15, wherein the capping layer includes aluminum.

19. The method of claim 18, wherein the first conductive material includes nickel (Ni) and the second conductive material includes copper (Cu).

20. The method of claim 11, further comprising covering the encapsulation material with the additive material and the electrical connection by forming an encapsulation material without an additive material on the encapsulation material with the additive material and on the electrical connection.
